(19) United States
(12) Patent Application Publication
(10) Pub. No.: US 2026/0324398 A1
(43) Pub. Date: Oct. 15, 2026

(54) PARALLEL BACKSIDE VIA DEVICE, LAYOUT, AND METHOD

(71) Applicant: TAIWAN SEMICONDUCTOR MANUFACTURING COMPANY, LTD., Hsinchu (TW)

(72) Inventors: Guo-Huei WU, Hsinchu (TW); Po-Wen CHENG, Hsinchu (TW); Wei-Ling CHANG, Hsinchu (TW)

(21) Appl. No.: 19/323,329

(22) Filed: Sep. 9, 2025

Related U.S. Application Data
(60) Provisional application No. 63/788,284, filed on Apr. 14, 2025.

(51) Int. Cl. H10W 20/43; H10D 89/10; H10W 20/00; H10W 20/40; H10W 20/41; H10W 20/42

(52) U.S. Cl. CPC H10W 20/43; H10D 89/10; H10W 20/0693; H10W 20/422; H10W 20/427; H10W 20/498; H10W 20/435

(57) ABSTRACT

An IC device includes first and second adjacent active areas extending horizontally in a front side of a semiconductor substrate, first and second adjacent metal-diffusion (MD) segments perpendicular to, overlying and electrically connected to the first and second active areas, a frontside via overlying, and electrically connected to the first MD segment between the first and second active areas, a frontside metal segment overlying and electrically connected to the frontside via and extending horizontally, a backside metal segment extending horizontally, first and second backside vias extending between and electrically connected to the backside metal segment and the first active area, and third and fourth backside vias extending between and electrically connected to the backside metal segment and the second active area. The first and third backside vias are vertically aligned with the first MD segment and the second and fourth backside vias are vertically aligned with the second MD segment.

### PRIORITY CLAIM

The present application claims the priority of U.S. Provisional Application No. 63/788,284, filed Apr. 14, 2025, which is incorporated herein by reference in its entirety.

### BACKGROUND

The ongoing trend in miniaturizing integrated circuits (ICs) has resulted in progressively smaller devices which consume less power, yet provide more functionality at higher speeds than earlier technologies. Such miniaturization has been achieved through design and manufacturing innovations tied to increasingly strict specifications. Various electronic design automation (EDA) tools are used to generate, revise, and verify designs for semiconductor devices while ensuring that IC structure design and manufacturing specifications are met.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1D are diagrams of an IC device, in accordance with some embodiments.

FIGS. 2A and 2B are plan views of an IC device and layout diagram, in accordance with some embodiments.

FIG. 3 is a plan view of an IC device and layout diagram, in accordance with some embodiments.

FIG. 4 is a plan view of an IC device and layout diagram, in accordance with some embodiments.

FIG. 5 is a plan view of an IC device and layout diagram, in accordance with some embodiments.

FIG. 6 is a plan view of an IC device and layout diagram, in accordance with some embodiments.

FIG. 7 is a plan view of an IC device and layout diagram, in accordance with some embodiments.

FIG. 8 is a plan view of an IC device and layout diagram, in accordance with some embodiments.

FIG. 9 is a flowchart of a method of manufacturing an IC device, in accordance with some embodiments.

FIG. 10 is a flowchart of a method of manufacturing an IC device, in accordance with some embodiments.

FIG. 11 is a block diagram of an IC layout diagram generation system, in accordance with some embodiments.

FIG. 12 is a block diagram of an IC manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, an integrated circuit (IC) device and corresponding layout diagram and manufacturing method include two adjacent active areas in a frontside of a semiconductor substrate, two adjacent metal-diffusion (MD) segments overlying the active areas, a frontside via and metal segment overlying and electrically connected to at least one of the MD segments, and a backside metal segment electrically connected to the frontside metal segment through four backside vias extending to the active areas and aligned with the MD segments.

The IC device is thereby capable of being included in a network, e.g., a power distribution network, in which multiple parallel paths, e.g., at least nine, between frontside and backside metal segments act to maintain a predetermined performance level of a functional cell in the event of an open circuit in a backside via configured to provide an electrical connection to the cell.

Compared to other approaches, e.g., those including single electrical connections to cells, the IC device is thereby capable of increasing circuit reliability and reducing risks due to current-resistance (IR) voltage drops and/or electromigration (EM) such that overall performance is improved.

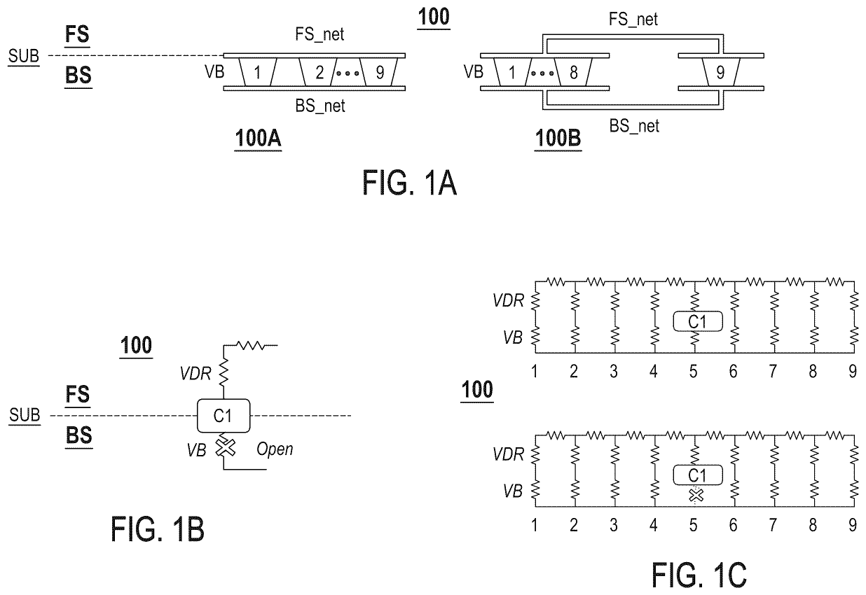

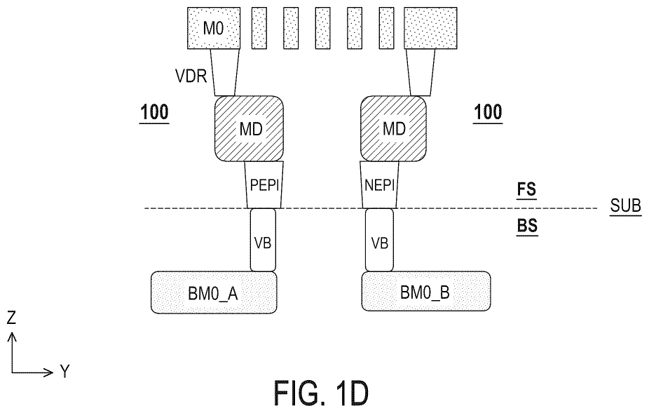

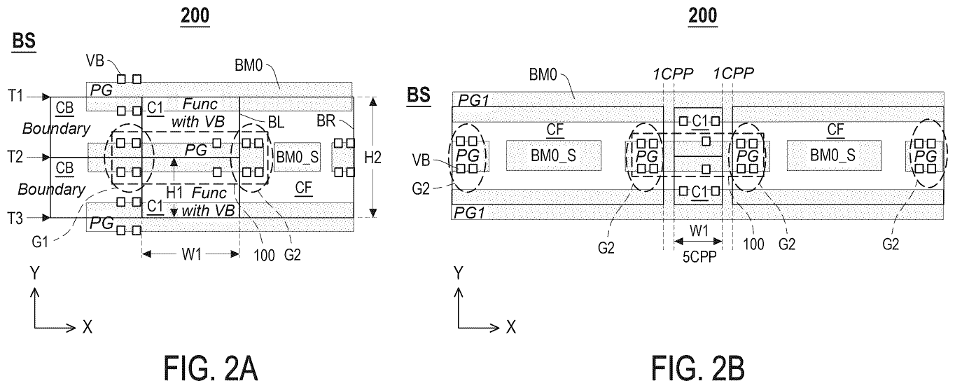

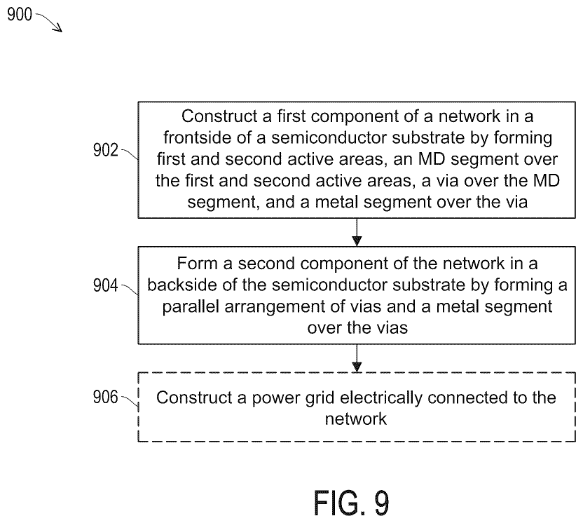

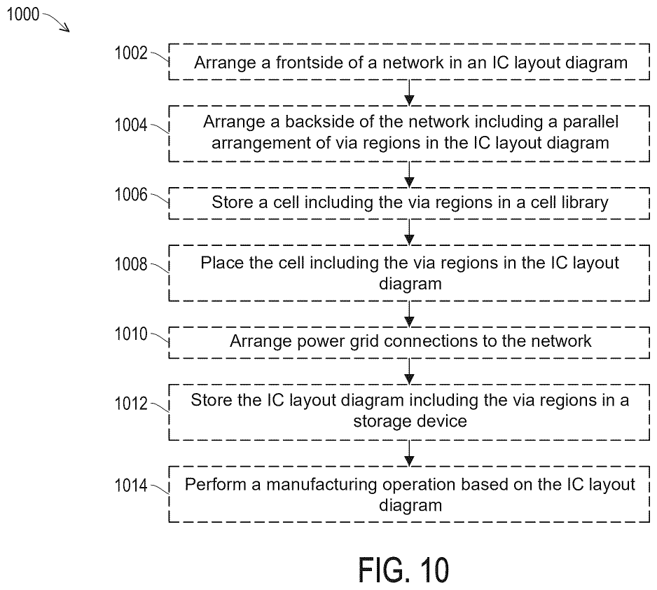

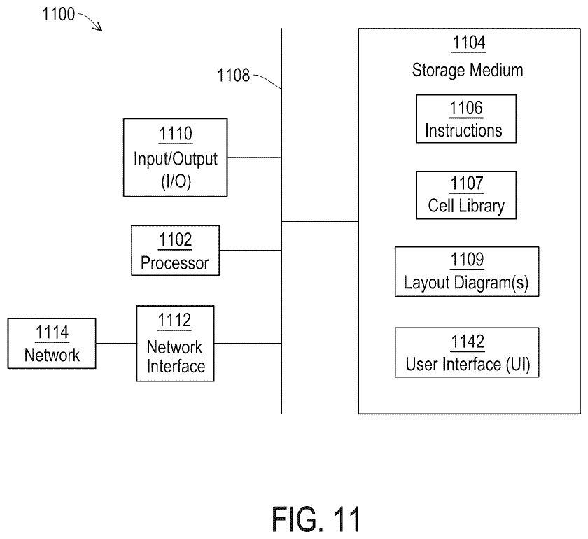

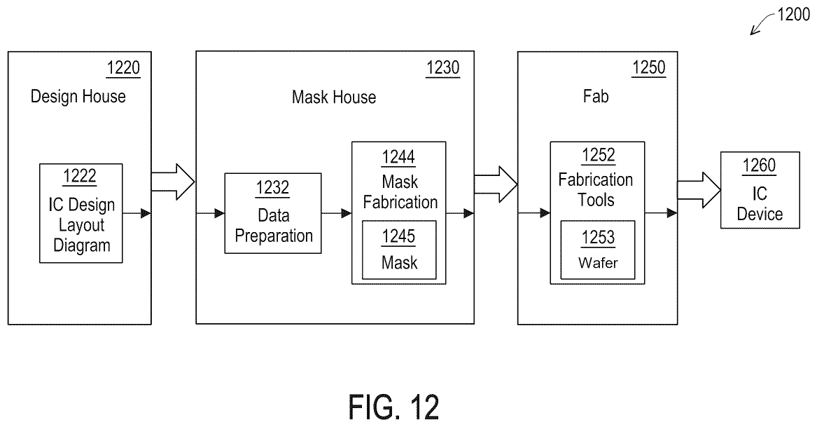

As discussed below, in accordance with various embodiments, FIGS. 1A-1D depict diagrams and a cross-sectional view of a combined frontside/backside network 100, and FIGS. 2A-8 depict plan views of IC layout diagrams/devices 200-800, FIG. 9 is a flowchart of a method 900 of manufacturing an IC device, e.g., IC device 100-800, based on a corresponding one or more instances of IC layout diagram 100-800, FIG. 10 is a flowchart of a method 1000 of manufacturing an IC device by generating one or more instances of IC layout diagram 100-800, e.g., using a system 1100 discussed below with respect to FIG. 11 and/or in accordance with an IC manufacturing flow and associated IC manufacturing system 1200 discussed below with respect to FIG. 12.

Each of the figures herein, e.g., FIGS. 1A-8, is simplified for the purpose of illustration. The figures are views of IC structures, devices, and layout diagrams with various features included and excluded to facilitate the discussion below. In various embodiments, an IC structure, device and/or layout diagram includes one or more features corresponding to power distribution structures, metal interconnects, contacts, vias, gate structures, source/drain (S/D) structures, bulk connections, or other transistor elements, isolation structures, or the like, in addition to the features depicted in FIGS. 1A-8.

In each embodiment of frontside/backside network 100, also referred to as network 100 or IC layout diagram/device 100 in some embodiments, and IC layout diagrams/devices 200-800 depicted in FIGS. 1A-8, some or all of the reference designators represent both IC device features and the IC layout features used to at least partially define the corresponding IC device features in a manufacturing process, e.g., method 900 discussed below with respect to FIG. 9 and/or the IC manufacturing flow associated with IC manufacturing system 1200 discussed below with respect to FIG. 12. Accordingly, each embodiment of IC layout diagrams/devices 100-800 depicted in FIGS. 1A-8 represents both an IC layout diagram 100-800 and a corresponding IC device 100-800.

In FIGS. 1A-8, for the purpose of clarity, all instances of each feature included in the corresponding instance of IC layout diagram/device 100-800 are not necessarily labeled. Unless otherwise indicated, the numbers of instances of the various features depicted in FIGS. 1A-8, e.g., numbers of rows, tracks, or cells in a given row, are non-limiting examples provided for the purpose of illustration. Embodiments of IC layout diagram/device 100-800 including numbers of instances of features other than those depicted in FIGS. 1A-8 are within the scope of the present disclosure.

In some embodiments, a portion or all of an embodiment of IC layout diagram/device 100-800 corresponds to an IC cell. In some embodiments, a cell, e.g., a cell C1 or CF, corresponds to an inverter, a buffer, a logic gate, a clock or other signal source, or other functional element, including a plurality of transistors isolated from adjacent elements by a pair of dummy gates and configured to perform a specified function. In some embodiments, a cell, e.g., a cell CB, corresponds to a boundary of an IC including multiple cells, e.g., a memory circuit, a processor, an integrated logic device, a system or the like, and the cell is configured to isolate the IC from adjacent circuits by including corresponding features, e.g., transistors, capacitive devices, gates, and/or dummy gates, or no features, between a pair of dummy gates.

Each embodiment of IC layout diagrams/devices 100-800 discussed below includes arrangements of some or all of at least one of a semiconductor substrate, a well, an active region/area, a S/D region/structure, an MD region/segment, a cut MD region, a gate region/structure, a cut gate region, an isolation feature/structure, a metal region/segment, a via region/structure, and/or a feed-through via FTV region/structure, each discussed below.

A semiconductor substrate, e.g., a substrate SUB, is a portion, e.g., a die, or all of a semiconductor wafer, e.g., a silicon (Si) wafer, or an epitaxial Si layer, suitable for forming one or more IC devices, e.g., IC devices 100-800. In each of the embodiments discussed below, a semiconductor substrate includes a front side, e.g., a front side FS, within which a first subset of the features of the IC devices are formed through a first set of manufacturing processes, e.g., front-end-of-line (FEOL) processes, middle-end-of-line (MEOL) processes, and back-end-of-line (BEOL) processes, and a back side, e.g., a back side BS, within which a second subset of the features of the IC devices are formed through a second set of manufacturing processes, e.g., backside metallization processes, performed after the first set of manufacturing processes are performed.

In some embodiments, the semiconductor substrate is thinned by performing one or more thinning operations between the first and second sets of manufacturing operations. In some embodiments, the front and back sides are separated by a plane extending in X and Y directions.

A well is a continuous portion of the semiconductor substrate including one or more dopants. In various embodiments, a well is a p-well based on the semiconductor substrate portion including one or more acceptor dopants, e.g., boron (B) or aluminum (Al), or an n-well based on the semiconductor substrate portion including one or more donor dopants, e.g., phosphorous (P) or arsenic (As).

An active region/area, e.g., an active region/area AA, is a region in an IC layout diagram included in a manufacturing process as part of defining an active area, also referred to as an oxide diffusion or definition (OD), in the semiconductor substrate, either directly or in an n-well or p-well region/area, in which one or more IC device features, e.g., a S/D structure, is formed. In some embodiments, an active area is an n-type or p-type active area of a planar transistor, a FinFET, or a GAA transistor. In various embodiments, an active area (structure) includes one or more of a semiconductor material, e.g., silicon (Si), silicon-germanium (SiGe), silicon-carbide (SiC), or the like, a dopant material, e.g., boron (B), phosphorous (P), arsenic (As), gallium (Ga), or another suitable material.

In some embodiments, an active region/area is a region in the IC layout diagram included in the manufacturing process as part of defining a nano-sheet structure, e.g., a continuous volume of one or more layers of one or more semiconductor materials having either n-type or p-type doping. In various embodiments, individual nano-sheet layers include a single monolayer or multiple monolayers of a given semiconductor material. In some embodiments, nano-sheet layers correspond to an n-type epitaxial structure, e.g., an epitaxial structure NEPI, or a p-type epitaxial structure, e.g., an epitaxial structure PEPI.

A S/D region/structure is a region in the IC layout diagram included in the manufacturing process as part of defining a S/D structure, also referred to as a semiconductor structure in some embodiments, configured to have a doping type opposite that of the corresponding active region/area. In some embodiments, a S/D region/structure is configured to have lower resistivity than an adjacent channel feature, e.g., a portion of the corresponding active region/area of a planar FET, a fin structure of a FinFET, or a gate structure of a GAA transistor. In some embodiments, a S/D region/structure includes one or more portions having doping concentrations greater than one or more doping concentrations present in the corresponding channel feature. In some embodiments, a S/D region/structure includes one or more epitaxial regions of a semiconductor material, e.g., Si, SiGe, and/or silicon-carbide SiC.

An MD region/segment, e.g., MD region/segment MD, is a conductive region in the IC layout diagram included in the manufacturing process as part of defining an MD segment, also referred to as a conductive segment or MD conductive line or trace, in and/or on the semiconductor substrate, e.g., between a lowermost metal layer and an active (OD) area. In some embodiments, an MD region overlaps an active area at a location of a S/D region in the IC layout diagram, and the corresponding MD segment contacts and is electrically connected to the S/D structure of the active area.

In some embodiments, an MD segment includes a portion of at least one metal layer, e.g., a contact layer, overlying and contacting the substrate and having a thickness sufficiently small to enable formation of an insulation layer between the MD segment and an overlying metal layer, e.g., the first metal layer. In various embodiments, an MD segment includes one or more of copper (Cu), silver (Ag), tungsten (W), titanium (Ti), nickel (Ni), tin (Sn), aluminum (Al) or another metal or material suitable for providing a low resistance electrical connection between IC structure elements, i.e., a resistance level below a predetermined threshold corresponding to one or more tolerance levels of a resistance-based effect on circuit performance.

In various embodiments, an MD segment includes a section of the semiconductor substrate and/or an epitaxial layer having a doping level, e.g., based on an implantation process, sufficient to cause the segment to have the low resistance level. In various embodiments, a doped MD segment includes one or more dopant materials having doping concentrations of about 1*1016 per cubic centimeter (cm⁻³) or greater.

In some embodiments, a manufacturing process includes two MD layers, and an MD region/segment, e.g., MD region/segment MD, refers to one or both of the MD layers.

A cut MD region is a region in the IC layout diagram included in the manufacturing process as part of defining a portion of an MD segment that is removed and replaced with one or more dielectric materials, e.g., an isolation structure, in operations performed subsequent to the MD segment formation, thereby electrically isolating the adjacent portions of the MD segment from each other.

A gate region/structure, e.g., a gate region/structure G or DG, is a region in the IC layout diagram included in the manufacturing process as part of defining a gate structure. A gate structure is a volume including one or more conductive segments, e.g., a gate electrode, including one or more conductive materials, e.g., polysilicon, copper (Cu), aluminum (Al), tungsten (W), cobalt (Co), ruthenium (Ru), or one or more other metals or other suitable materials, substantially surrounded by one or more insulating materials, the one or more conductive segments thereby being configured to control a voltage provided to an adjacent gate dielectric layer.

A gate dielectric layer, e.g., a gate dielectric layer of a gate structure G or DG, is a volume including one or more insulating materials, e.g., silicon dioxide, silicon nitride (Si₃N₄), and/or one or more other suitable material such as a low-k material having a k value less than 3.8 or a high-k material having a k value greater than 3.8 or 7.0 such as aluminum oxide (Al₂O₃), hafnium oxide (HfO₂), tantalum pentoxide (Ta₂O₅), or titanium oxide (TiO₂), suitable for providing a high electrical resistance between IC structure elements, i.e., a resistance level above a predetermined threshold corresponding to one or more tolerance levels of a resistance-based effect on circuit performance.

In some embodiments, a gate region/structure corresponds to a dummy gate region/structure, e.g., dummy gate region/structure DG. In some embodiments, a dummy gate region/structure includes a gate electrode electrically connected, e.g., tied-off, to one or more features, e.g., a power rail or other metal segment or an adjacent instance of a S/D region/structure such that a transistor corresponding to the dummy gate region/structure and overlapping/underlying active region/area is switched off by design. In some embodiments, a dummy gate region/structure is part of a corresponding dummy transistor. In some embodiments, a dummy transistor is a non-functional transistor.

In some embodiments, a dummy gate region/structure that overlaps/overlies an edge of an active region/area is referred to as a continuous poly on oxide definition edge (CPODE) region/structure. In some embodiments, a CPODE region refers to a region in the IC layout diagram included in the manufacturing process as part of initially defining a gate structure that is subsequently altered, e.g., removed, along with underlying active area portion(s) in some embodiments, and replaced with one or more dielectric materials. In some embodiments, a CPODE region is thereby included in the manufacturing process as part of defining an isolation region.

In some embodiments, gate regions/structures and dummy gate regions/structures are spaced apart, e.g., in the X direction, by a distance corresponding to a contacted poly pitch (CPP).

A cut gate region, also referred to as a cut poly region in some embodiments, is a region in the IC layout diagram included in the manufacturing process as part of defining a portion of a gate electrode that is removed and replaced with one or more dielectric materials, e.g., an isolation structure, in operations performed subsequent to the gate electrode formation, thereby electrically isolating the adjacent portions of the gate electrode from each other.

An isolation feature/structure is a feature including one or more regions in the IC layout diagram included in the manufacturing process as part of defining an isolation structure configured to electrically isolate adjacent features from each other, e.g., adjacent gate electrode portions based on a cut gate region of the IC layout diagram. In some embodiments, an isolation feature/structure includes a dielectric region/volume positioned between adjacent features, e.g., MD regions/segments MD or gate regions/structures G or DG, corresponding to a cutting process, e.g., a cut MD or cut gate process. A dielectric region is a region in the IC layout diagram included in the manufacturing process as part of defining a volume including one or more insulating materials.

A metal line or region, e.g., a frontside metal region/segment M0 or backside metal region/segment BM0 or BM0_S, is a region in the IC layout diagram included in the manufacturing process as part of defining a metal line structure, or segment, including one or more conductive materials, e.g., polysilicon, copper (Cu), aluminum (Al), tungsten (W), cobalt (Co), ruthenium (Ru), or one or more other metals or other suitable materials, in a given frontside or backside metal layer of the manufacturing process.

In some embodiments, a metal region/segment corresponds to a first frontside metal layer (also referred to as a metal zero layer M0 or frontside metal zero layer M0 in some embodiments), or a second or higher level frontside metal layer of the manufacturing process. In some embodiments, a second frontside metal layer is referred to as a metal one layer or frontside metal one layer.

In some embodiments, a metal region/segment corresponds to a first backside metal layer (also referred to as a backside metal zero layer BM0 or BM0_S in some embodiments), or a second or higher level backside metal layer of the manufacturing process. In some embodiments, a second backside metal layer is referred to as a backside metal one layer.

In some embodiments, a metal region/segment, e.g., a power rail, corresponds to a component of a power distribution network, e.g., frontside/backside network 100, configured to distribute one of a power supply voltage, e.g., a power supply voltage VDD, or a reference or ground voltage, e.g., a reference voltage VSS. The power distribution network component is electrically connected to one or more features, e.g., additional metal regions/segments, via regions/structures, and/or FTV regions/structures, configured to distribute the corresponding power supply or reference voltage and be electrically isolated from IC components outside the distribution network.

In some embodiments, a metal region/segment corresponds to a signal line included in a signal path configured to electrically connect a first device or circuit output terminal, e.g., a S/D region/structure, to one or more second device or circuit input terminals, e.g., one or more gate electrodes. The signal line is electrically connected to one or more features, e.g., additional metal regions/segments, via regions/structures, and/or FTV regions/structures, configured to propagate a signal from the output terminal to the input terminal and be electrically isolated from IC components outside the signal path. In various embodiments, a signal line is configured to propagate a clock or other timing signal, a pulse signal, a control signal, a logic signal, or the like.

A via region/structure, e.g., a via region/structure VD or VDR is a region in the IC layout diagram included in the manufacturing process as part of defining a via structure including one or more conductive materials configured to provide an electrical connection between a first, e.g., overlying, conductive structure, e.g., a metal segment M0 and a second, e.g., underlying, conductive structure, e.g., a metal segment M0, a gate electrode of a gate structure G or DG, an instance of MD segment MD, or a S/D structure, aligned with the first conductive structure in a Z direction.

In some embodiments, a via region/structure VD corresponds to the underlying conductive structure being a S/D region/structure or MD region/segment MD and the overlying conductive structure being a frontside metal region/segment M0, a via region/structure VDR corresponds to the underlying conductive structure being a S/D region/structure or MD region/segment MD and the overlying conductive structure being a frontside metal region/segment M0 corresponding to a power distribution network, and/or a via region/structure corresponds to the underlying conductive structure being a frontside metal region/segment M0.

In some embodiments, a via region/structure, e.g., via region/structure VB, also referred to as a backside via region/structure VB in some embodiments, corresponds to an electrical connection between the first conductive structure being an active area AA or epitaxial structure NEPI or PEPI and the second conductive structure being a backside conductive structure such as backside metal segment BM0.

In some embodiments, a via region/structure, e.g., a backside via region/structure VB, has one or more cross-sectional dimensions that correspond to, e.g., are approximately equal to, one or more cross-sectional dimensions of the overlying and/or underlying region/structure, e.g., a dimension in a first one of the X or Y direction such as a length or width that matches a dimension in the same one of the X or Y direction of one of the overlying or underlying region/structure, e.g., a corresponding length or width. In some embodiments, a backside via region/structure VB has a cross-sectional dimension approximately equal to a width of an overlying active region/area AA and/or epitaxial region/structure NEPI or PEPI. In some embodiments, a backside via region/structure VB has a cross-sectional dimension approximately equal to a width of an overlying MD region/segment MD.

An FTV region/structure, e.g., an FTV region/structure B_FTV, is a region in the IC layout diagram included in the manufacturing process as part of defining an FTV structure including one or more conductive materials configured to provide an electrical connection between a first, e.g., overlying, conductive structure, e.g., a metal segment M0, an MD segment MD, or a gate electrode of a gate structure G or DG, and a second, e.g., underlying, conductive structure, e.g., a metal segment BM0, positioned in a backside metal layer and aligned with the first conductive structure in the Z direction. In some embodiments, the underlying conductive structure is a signal line or a power distribution component such as a power rail.

In some embodiments, an FTV region/structure, e.g., FTV structure B_FTV, has one or more cross-sectional dimensions greater than one or more cross-sectional dimensions of the overlying and/or underlying region/structure, e.g., a dimension in a first one of the X or Y direction such as a length or width greater than a dimension in the same one of the X or Y direction of one of the overlying or underlying region/structure, e.g., a corresponding length or width. In some embodiments, an FTV has a cross-sectional dimension greater than a width of an overlying MD region/structure or a width of an overlying gate structure G or DG.

In some embodiments, an FTV has one or both cross-sectional dimensions that extend beyond the corresponding MD region/structure or gate structure G or DG in one or both of a width or length direction. In some embodiments, an FTV has a cross-sectional dimension that spans multiple instances of an overlying region/structure, e.g., multiple instances of MD region/segment MD or gate region/structure G or DG. In some embodiments, an FTV has a cross-sectional dimension that spans a minimum of three times a gate pitch of instances of a gate region/structure.

FIG. 1A depicts a side view of network 100, FIGS. 1B and 1C depict schematic diagrams of network 100, and FIG. 1D depicts a cross-sectional view of network 100 features, in accordance with some embodiments. In various embodiments, network 100 is configured as some or all of a power distribution network or signal path of an IC.

As illustrated in FIG. 1A, network 100 includes a network component FS_net in frontside FS of substrate SUB and a network component BS_net in backside BS of substrate SUB. In various embodiments, network component FS_net includes features, e.g., instances of active region/area AA, MD region/segment MD, via region/structure VDR, and metal region/segment M0, arranged in frontside FS, and network component BS_net includes features, e.g., instances of via region/structure VB and metal region/segment BM0, arranged in backside BS, as further discussed below with respect to IC layout diagram/device 200.

FIG. 1A depicts two embodiments of network 100 in which each of network component FS_net and network component BS_net is electrically connected to each of multiple instances of via region/structure VB. One embodiment (labelled as 100A in FIG. 1A) includes the features of each of network component FS_net and network component BS_net arranged in a single layer and one embodiment (labelled as 100B in FIG. 1A) includes the features of each of network component FS_net and network component BS_net arranged in two layers. Other arrangements by which each of network component FS_net and network component BS_net is electrically connected to each of the multiple instances of via region/structure VB, e.g., a single one of network component FS_net or BS_net including features arranged in a single layer or one or both of network component FS_net or BS_net including features arranged in three or more layers, are within the scope of the present disclosure.

In the embodiment depicted in FIGS. 1A and 1C, network 100 includes a total of nine instances of via region/structure VB electrically connected to each of network component FS_net and network component BS_net. In some embodiments, network 100 includes fewer or greater than nine instances of via region/structure VB electrically connected to each of network component FS_net and network component BS_net.

FIG. 1B illustrates a condition in which an instance of via structure VB is configured by design to be electrically connected to each of cell C1 and an underlying backside network feature and thereby included in a low resistance path between cell C1 and the underlying feature, but instead is an open circuit or otherwise relatively high resistance path between cell C1 and the underlying feature, e.g., based on a defect manifested during or after one or more manufacturing operations.

As illustrated in FIGS. 1B and 1C, by being electrically connected through network 100 including electrical connections to each of network component FS_net and network component BS_net, in the case in which the instance of via structure VB in backside BS corresponding to cell C1 is an open circuit, the electrical connection from cell C1 to network 100 is maintained through an instance of via structure VDR in frontside FS electrically connected to cell C1 and additional instances of via regions/structures VB and VDR of network 100 arranged in parallel.

Because of the open circuit at the instance of via structure VB corresponding to cell C1, a path resistance of the maintained electrical connection between cell C1 and network 100 increases in comparison to an otherwise equivalent path resistance in which the electrical connection between cell C1 and network 100 includes the instance of via structure VB electrically connected to cell C1. In operation, the increased path resistance causes an increase in an IR voltage drop between cell C1 and network 100 capable of compromising the function and/or reliability of cell C1.

As the total number of instances of via region/structure VB electrically connected to each of network components FS_net and BS_net increases, the number of parallel paths in network 100 available to compensate for an open circuit at the instance of via region/structure VB corresponding to cell C1 increases, thereby decreasing the path resistance of the maintained electrical connection and reducing the effect of the open circuit on the operation of cell C1.

In some embodiments, a minimum total number of instances of via region/structure VB electrically connected to each of network components FS_net and BS_net corresponds to a maximum specified IR voltage drop for cell C1 and/or the IC including cell C1. In some embodiments, a minimum of nine instances of via region/structure VB electrically connected to each of network components FS_net and BS_net corresponds to a maximum specified IR voltage drop of 1.5 percent (%) of a power supply voltage level of cell C1 and/or the IC including cell C1. Embodiments in which network 100 includes the minimum total number of instances of via region/structure VB greater than or less than nine are within the scope of the present disclosure.

In the embodiment depicted in FIGS. 1A-1C, each instance of via region/structure VB of network 100 is arranged in series with a corresponding instance of via region/structure VDR. In some embodiments, e.g., as discussed below with respect to IC layout diagram/device 200, multiple instances of via region/structure VB of network 100 are arranged in series with a corresponding single instance of via region/structure VDR such that a total number of instances of via region/structure VB is greater than a total number of instances of via region/structure VDR.

FIG. 1D depicts a cross-sectional view of network 100 features and the Y and Z directions, in accordance with some embodiments. The embodiment depicted in FIG. 1D includes instances BM0_A and BM0_B of backside metal region/segment BM0 in backside BS, each corresponding to a portion of a separate instance of network 100. In some embodiments, backside metal regions BM0_A and BM0_B correspond to separate mask sets included in the manufacturing process as part of defining corresponding backside metal segments BM0_A and BM0_B.

In some embodiments, the instance of network 100 including region/segment BM0_A is configured as part of a power supply voltage, e.g., voltage VDD, distribution network and the instance of network 100 including region/segment BM0_B is configured as part of a reference voltage, e.g., voltage VSS or ground, distribution network.

In each instance of network 100, an instance of via region/structure VB overlaps/overlies and is electrically connected to the corresponding one of backside metal region/segment BM0_A or metal region/segment BM0_B, a corresponding one of epitaxial region/structure PEPI or NEPI (of an active region/area, e.g., active region/area AA discussed below), overlaps/overlies and is electrically connected to the corresponding instance of via region/structure VB, an instance of MD region/segment MD overlaps/overlies and is electrically connected to the corresponding epitaxial region/structure PEPI or NEPI, an instance of via region/structure VDR overlaps/overlies and is electrically connected to the corresponding instance of MD region/segment MD, and an instance of metal region/segment M0 overlaps/overlies and is electrically connected to the corresponding instance of via region/structure VDR.

Each instance of network 100 depicted in FIG. 1D thereby includes network component BS_net including at least one instance each of backside metal region/segment BM0_A or BM0_B and via region/structure VB, and network component FS_net including at least one instance each of epitaxial region/structure PEPI or NEPI, MD region/segment MD, via region/structure VDR, and metal region/segment M0 configured as discussed above with respect to FIGS. 1A-1C.

In some embodiments, an instance of network 100 depicted in FIG. 1D, e.g., including additional instances of one or more of the relevant features as discussed above, is included in at least one embodiment of IC layout diagram/device 200 as discussed below.

An IC device including cell C1 electrically connected to network 100 is thereby configured to include multiple parallel paths between frontside and backside network components capable of maintaining a predetermined performance level of cell C1 in the event of an open circuit in a corresponding via structure VB configured to provide an electrical connection to cell C1. Compared to other approaches, e.g., those including single electrical connections to cells, the IC device is thereby capable of increasing circuit reliability and reducing risks due to IR voltage drops and/or EM such that overall performance is improved.

FIGS. 2A and 2B depict plan views of IC layout diagram/device 200 and the X and Y directions, in accordance with some embodiments. Each of the embodiments of IC layout diagram/device 200 depicted in FIGS. 2A and 2B includes two instances of cell C1 adjacent to each other in the Y direction, corresponding instances of network 100, and instances of backside metal region/segment BM0 and BM0_S, each discussed above with respect to FIGS. 1A-1D. The embodiments of IC layout diagram/device 200 depicted in FIGS. 2A and 2B also include instances of boundary cell CB and/or functional cell CF, each discussed below.

The depictions of the instances of cell C1, boundary cell CB, and functional cell CF in FIGS. 2A and 2B are simplified for the purpose of illustration. In various embodiments, one or more of the instances of cell C1, boundary cell CB, or functional cell CF includes features, e.g., gate/dummy gate regions/structures, MD regions/segments, via regions/structures, or metal regions/segments, in addition to those depicted in FIGS. 2A and 2B. Each instance of cell C1, CB, and CF includes (vertical) borders BL and BR (a single instance labeled for clarity) extending in the Y direction and (horizontal) borders (not labeled) extending in the X direction between border BL at the most negative X location and border BR at the most positive X location.

The instances of backside metal region/segment BM0 extend in the X direction and are aligned along tracks T1-T3 corresponding to the top and bottom horizontal borders of the instances of cell C1 such that a cell height H1 of cell C1 corresponds to a pitch (not separately labeled) of tracks T1-T3.

Alternating instances (in the Y direction) of backside metal region/segment BM0 are configured as parts of first and second ones of a power supply voltage distribution network, e.g., corresponding to metal region/segment BM0_A discussed above, or a reference voltage distribution network, e.g., corresponding to metal region/segment BM0_B discussed above, such that instances of backside metal region/segment BM0 aligned along track T2 are configured as part of the first one of the power supply or reference voltage distribution networks, and instances of backside metal region/segment BM0 aligned along tracks T1 and T3 are configured as part of the second one of the power supply or reference voltage distribution networks.

As depicted in FIGS. 2A and 2B, a single continuous instance of backside metal region/segment BM0 is aligned along each of tracks T1 and T3, and multiple instances of backside metal region/segment BM0 are aligned along track T2. The instances of backside metal region/segment BM0 configured as part of the first one of the power supply or reference voltage distribution networks are arranged alternately in the X direction with instances of backside metal region/segment BM0_S aligned along track T2 and otherwise configured, e.g., as part of either a clock or other signal pin and/or an output pin, or the second one of the power supply or reference voltage distribution networks.

In some embodiments, as depicted in FIGS. 2A and 2B, the instances of backside metal region/segment BM0 configured as part of either one of the power supply or reference voltage distribution networks are referred to as instances of a power grid segment PG and the instances of backside metal region/segment BM0_S are referred to as instances of a broken BM0 or output BM0 pin.

In the embodiment depicted in FIG. 2A, IC layout diagram/device 200 includes two instances of boundary cell CB having cell height H1 and adjacent in the X direction to instances of border BL of corresponding instances of cell C1, and functional cell CF having a cell height H2 equal to 2×H1 and adjacent in the X direction to instances of border BR of the instances of cell C1. In the embodiment depicted in FIG. 2B, IC layout diagram/device 200 includes two instances of functional cell CF adjacent in the X direction to the corresponding borders BL and BR of the instances of cell C1.

Each instance of cell C1 has a cell width W1 equal to a CPP multiple. In the embodiment depicted in FIG. 2B, the instances of cell C1 have width W1 equal to 5 CPP. Embodiments in which cell C1 has width W1 equal to other CPP multiples are within the scope of the present disclosure.

In the embodiment depicted in FIG. 2A, the instances of boundary cell CB and functional cell CF are separated by cell width W1 such that the cell C1 borders BL and BR are shared with those of the adjacent cells. In the embodiment depicted in FIG. 2B, instances of functional cell CF are separated by a distance greater than cell width W1 such that the cell C1 borders BL and BR are separated from borders BR and BL of each of the adjacent cells by a distance equal to CPP. In some embodiments, one or both cell C1 borders BL or BR are separated from corresponding borders BR or BL of adjacent cells by unequal distances and/or one or more distances greater than CPP, e.g., 2 CPP.

As depicted in FIG. 2A, each instance of boundary cell CB overlaps/overlies each of an instance of metal region/segment BM0 configured as part of the first one of the power supply or reference voltage distribution networks and an instance of metal region/segment BM0 configured as part of the second one of the power supply or reference voltage distribution networks. Each instance of boundary cell CB includes two instances of via region/structure VB that overlap/overlie each of the instances of metal region/segment BM0 adjacent to the first border of the corresponding instance of cell C1 corresponding to a group G1 of four instances of via region/structure VB.

As depicted in FIGS. 2A and 2B, each instance of functional cell CF overlaps/overlies two instances of metal region/segment BM0 aligned along track T2 and configured as part of the first one of the power supply or reference voltage distribution networks, two instances of metal region/segment BM0 aligned along tracks T1 and T3 and configured as part of the second one of the power supply or reference voltage distribution networks, and one instance of metal region/segment BM0_S aligned along track T2 between the corresponding two instances of metal region/segment BM0.

Each instance of functional cell CF includes a group G2 of four instances of via region/structure VB that overlap/overlie a first instance of metal region/segment BM0 configured as part of the first one of the power supply or reference voltage distribution networks and adjacent to the instances of border BL or BR of the two corresponding instances of cell C1, and a group G2 of four instances of via region/structure VB that overlap/overlie a second instance of metal region/segment BM0 configured as part of the first one of the power supply or reference voltage distribution networks and adjacent to a border BL or BR opposite the two corresponding instances of cell C1.

The numbers of instances of via region/structure VB that overlap/overlie a given instance of metal region/segment BM0 in a given instance of boundary cell CB or in an instance of group G2 in an instance of functional cell CF in IC layout diagram/device 200 as depicted in FIGS. 2A and 2B are non-limiting examples provided for the purpose of illustration. In various embodiments, IC layout diagram/device 200 includes one or more instances of boundary cell CB or functional cell CF that includes numbers of instances of via region/structure VB fewer than those depicted, e.g., none, or greater than those depicted, e.g., greater than four, that overlap/overlie the one or more corresponding instances of metal region/segment BM0, e.g. in group G2.

Each instance of cell C1 overlaps/overlies each of two instances of metal region/segment BM0 configured as part of corresponding first and second ones of the power supply or reference voltage distribution networks, and includes at least one instance of via region/structure VB that overlaps/overlies the instance of metal region/segment BM0 configured as part of the first one of the power supply or reference voltage distribution networks and at least one instance of via region/structure VB that overlaps/overlies the instance of metal region/segment BM0 configured as part of the second one of the power supply or reference voltage distribution networks.

In the embodiment depicted in FIG. 2A, the instance of metal region/segment BM0 configured as part of the first one of the power supply or reference voltage distribution networks is thereby configured to overlap/underlie the four instances of via region/structure VB in group G1 included in the instances of boundary cell CB, the four instances of via region/structure VB in group G2 included in the instance of functional cell CF, and the at least one instance of via region/structure VB included in each instance of cell C1.

In the embodiment depicted in FIG. 2B, the middle instance of metal region/segment BM0 (between the instances of metal region/segment BM0_S of the corresponding instances of functional cell CF) configured as part of the first one of the power supply or reference voltage distribution networks is thereby configured to overlap/underlie the four instances of via region/structure VB included in group G2 of each of the two instances of functional cell CF and the at least one instance of via region/structure included in each instance of cell C1.

In each embodiment, the corresponding instance of metal region/segment BM0 configured as part of the first one of the power supply or reference voltage distribution networks and the total of at least nine instances of via region/structure VB corresponding to each instance of cell C1 are thereby configured as a backside network component BS_net of an instance of network 100 discussed above with respect to FIGS. 1A-1D. Each of two instances of network 100 thereby includes the at least one instance of via region/structure VB in the corresponding instance of cell C1 and eight instances of via region/structure VB in the adjacent instances of boundary cell CB and/or functional cell CF that are shared between the two instances of network 100.

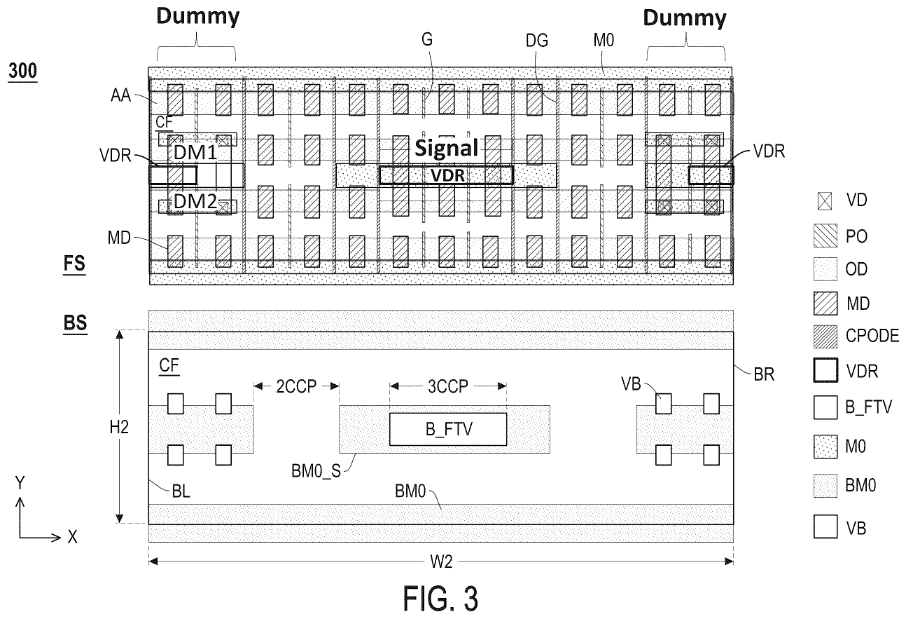

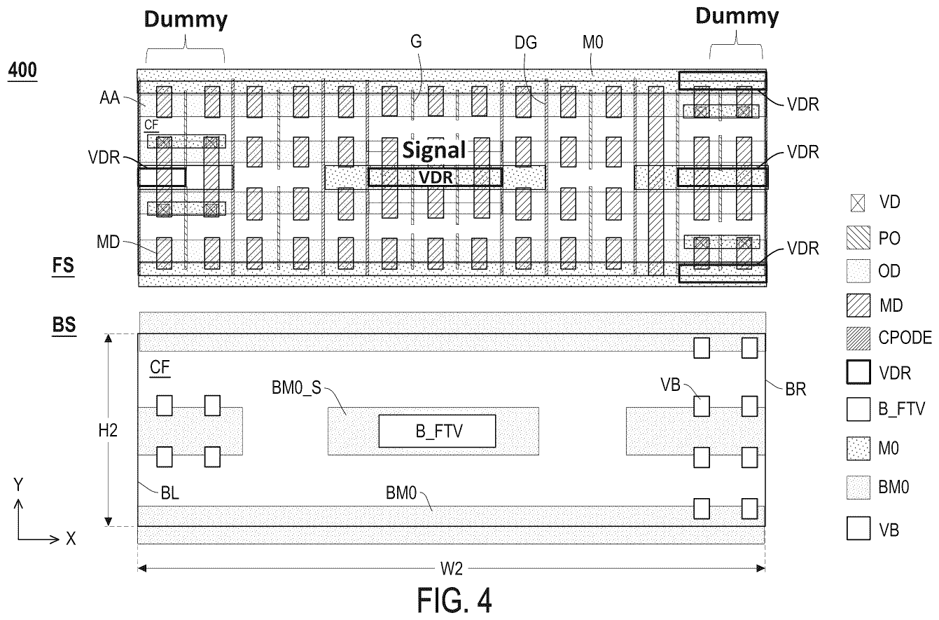

Each of the two instances of network 100 also includes features corresponding to frontside network component FS_net discussed above that are not depicted in FIGS. 2A and 2B for the purpose of clarity, non-limiting examples of which are discussed below with respect to FIGS. 3-8.

IC layout diagram/device 200 thereby includes each instance of cell C1 configured as depicted in FIGS. 2A and 2B to be electrically connected to the corresponding instance of network 100 including metal region/segment BM0 configured as part of the first one of the power supply or reference voltage distribution networks through at least nine instances of via region/structure VB.

Configurations of IC layout diagram/device 200 other than those depicted in FIGS. 2A and 2B in which an instance of cell C1 is electrically connected to a corresponding instance of network 100 are within the scope of the present disclosure. For example, in some embodiments, cells adjacent to an instance of cell C1 include fewer or greater numbers of instances of via region/structure VB such that the instance of cell C1 is electrically connected to the corresponding instance of network 100 through fewer or greater than nine instances of via region/structure VB.

In some embodiments, IC layout diagram/device 200 includes a single instance of cell C1, e.g., having a cell height of at least 2×H1, adjacent to instances of boundary cell CB and/or functional cell CF such that the instances of via region/structure VB included in the adjacent cells are not shared between multiple instances of network 100.

In various embodiments, IC layout diagram/device 200 includes a single instance of boundary cell CB, e.g., having a cell height of at least 2×H1, adjacent to one or more instances of cell C1 and/or includes one or more instances of boundary cell CB adjacent to each of the first and second borders of one or more instances of cell C1 and configured such that each instance of cell C1 is electrically connected to a corresponding instance of network 100.

By including the instances of cell C1, boundary cell CB, and/or functional cell FB configured such that each instance of cell C1 is electrically connected to a corresponding instance of network 100, each embodiment of IC layout diagram/device 200, including non-limiting examples 300-800 as further discussed below with respect to FIGS. 3-8, is capable of realizing the benefits discussed above with respect to network 100.

Each of FIGS. 3-8 depicts a plan view of a corresponding IC layout diagram/device 300, a non-limiting example of IC layout diagram/device 200, and the X and Y directions, in accordance with some embodiments. In each of FIGS. 3-8, an embodiment of functional cell FC included in the corresponding IC layout diagram/device 300-800 includes features corresponding to frontside FS that are depicted separately from those corresponding to backside BS.

The functional cell CF features corresponding to frontside FS include four instances of active region/area AA extending in the X direction and adjacent to each other in the Y direction.

Instances of features, e.g., active region/area AA, are considered to be adjacent to each other based on the space between the features being free from including additional instances of the same feature but in some embodiments including one or more instances of other feature types, e.g., one or more MD region/segment MD portions.

As ordered in the Y direction, first and fourth instances of active region/area AA are one of the p-type or n-type, e.g., corresponding to epitaxial region/structure PEPI or NEPI discussed above, and second and third instances of active region/area AA are the other of the p-type or n-type, the ordering corresponding to the ordering of the instances of backside metal region/segment BM0 configured as parts of either power supply or reference voltage distribution networks as discussed above.

As depicted in FIGS. 3-8, instances of gate region/structure G, dummy gate region/structure DG, and MD region/segment MD extend in the Y direction and overlap/overlie the instances of active region/area AA, instances of via regions/structures VD overlap/overlie instances of MD region/segment MD, instances of via regions/structures VDR extend in the X direction and overlap/overlie instances of MD region/segment MD, and instances of metal region/segment M0 extend in the X direction and overlap/overlie the instances of via regions/structures VD and VDR.

The functional cell CF features corresponding to backside FS include instances of via region/structure VB that overlap/underlie instances of active region/area AA and MD region/segment MD in frontside FS, e.g., as discussed above with respect to FIG. 1D, and overlap/overlie instances of backside metal region/segment BM0_S as discussed above with respect to FIGS. 2A and 2B.

In IC layout diagrams/devices 300 and 400 depicted in FIGS. 3 and 4, an FTV region/structure B_FTV in backside BS overlaps/overlies the instance of metal region/segment BM0_S, extends a distance 3 CPP in the X direction, and overlaps/underlies three instances of MD region/segment MD in frontside FS, and an instance of via region/structure VDR overlaps/overlies the three instances of MD region/segment MD and overlaps/underlies an instance of metal region/segment M0. The instance of backside metal region/segment BM0_S is thereby electrically connected to the instance of frontside metal region/segment M0 and configured as a signal output pin, e.g., a clock signal output pin.

Two instances of metal region/segment BM0 extend a distance 2 CPP each and are aligned with and separated from the instance of backside metal region/segment BM0_S by a distance 2 CPP in the X direction such that functional cell CF has a width W2 of 13 CPP in the embodiment depicted in FIGS. 3 and 4. Four instances of via region/structure VB overlap/overlie each of the two instances of metal region/segment BM0, a portion of each of the second and third instances of active region/area AA between two instances of dummy gate region/structure DG overlaps/overlies two of the four instances of via region/structure VB, and each of two instances of MD region/segment MD overlaps/overlies each of the portions of the second and third instances of active region/area AA and two of the instances of via region/structure VB.

Along border BL of functional cell CF, four instances of via region/structure VD overlap/overlie the two instances of MD region/segment MD, two instances of metal region/segment M0 overlap/overlie the four instances of via region/structure VD, and an instance of via region/structure VDR overlaps/overlies one of the instances of MD region/segment MD and overlaps/underlies an instance of metal region/segment M0 extending between the second and third instances of active region/area AA.

The frontside FS features are thereby arranged as dummy transistors DM1 and DM2 such that each of the four instances of via region/structure VB is electrically connected to the instance of metal region/segment M0 extending between the second and third instances of active region/area AA through the corresponding two instances of MD region/segment MD, four instances of via region/structure VD, two instances of metal region/segment M0, and single instance of via region/structure VDR. As arranged, the frontside FS features are thereby capable of being included in network component FS_net of a first instance of network 100 as discussed above with respect to FIGS. 1A-2B.

In IC layout diagram/device 300 depicted in FIG. 3, along border BR of functional cell CF, the frontside FS features are similarly arranged and thereby capable of being included in network component FS_net of a second instance of network 100.

In IC layout diagram/device 400 depicted in FIG. 4, along border BR of functional cell CF, the frontside FS features that overlap/overlie the corresponding four instances of via region/structure VB include, instead of the four instances of via region/structure VD and two instances of metal region/segment M0, an instance of via region/structure VDR overlaps/overlies each of the two instances of MD region/segment MD and overlaps/underlies the instance of metal region/segment M0 extending between the second and third instances of active region/area AA. The frontside FS features are thereby arranged as dummy transistors such that each of the four instances of via region/structure VB is electrically connected to the instance of metal region/segment M0 extending between the second and third instances of active region/area AA through the corresponding two instances of MD region/segment MD and single instance of via region/structure VDR capable of being included in network component FS_net of a second instance of network 100.

In IC layout diagram/device 400 depicted in FIG. 4, along border BR of functional cell CF, the backside BS features also include two instances of via region/structure VB that overlap/overlie each of the instances of metal region/segment BM0 that correspond to the top and bottom borders and overlap/underlie the corresponding first and fourth instances of active region/area AA.

The frontside FS features corresponding to each of the first and fourth instances of active region/area AA include two instances of MD region/segment MD that overlap/overlie the corresponding instance of a portion of active region/area AA between two instances of dummy gate region/structure DG, two instances of via region/structure VD that overlap/overlie the instances of MD region/segment MD, an instance of metal region/segment M0 that overlaps/overlies the instances of via region/structure VD, and an instance of via region/structure VDR that overlaps/overlies each of the two instances of MD region/segment MD and overlaps/underlies an instance of metal region/segment M0 aligned along the corresponding top or bottom horizontal border.

Each of the corresponding frontside FS features are thereby arranged as a dummy transistor such that each of the two instances of via region/structure VB is electrically connected to the corresponding instance of metal region/segment M0 extending along the corresponding border through the corresponding two instances of MD region/segment MD, two instances of via region/structure VD, instance of metal region/segment M0, and instance of via region/structure VDR. As arranged, the frontside FS features are thereby capable of being included in network component FS_net of third and fourth instances of network 100.

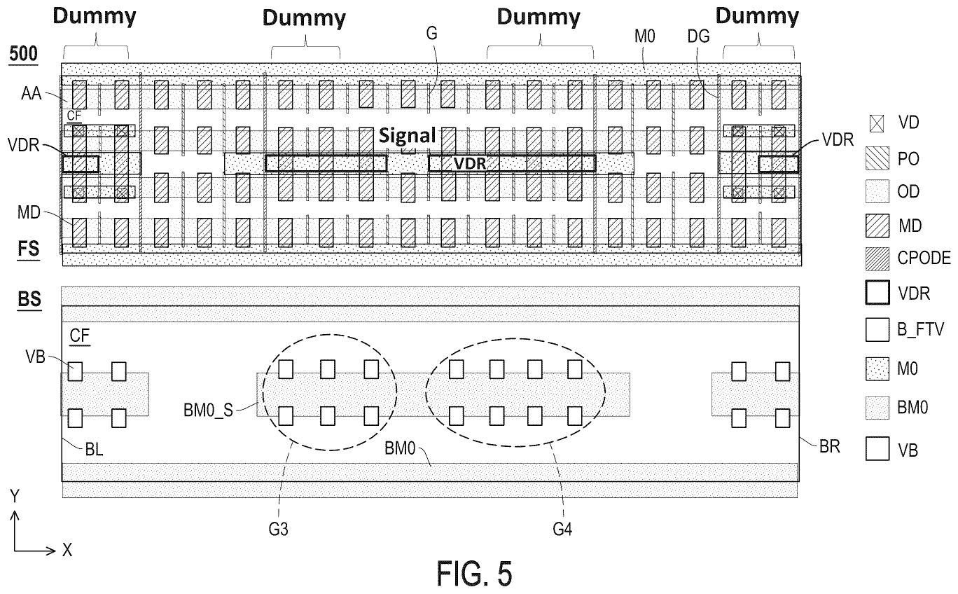

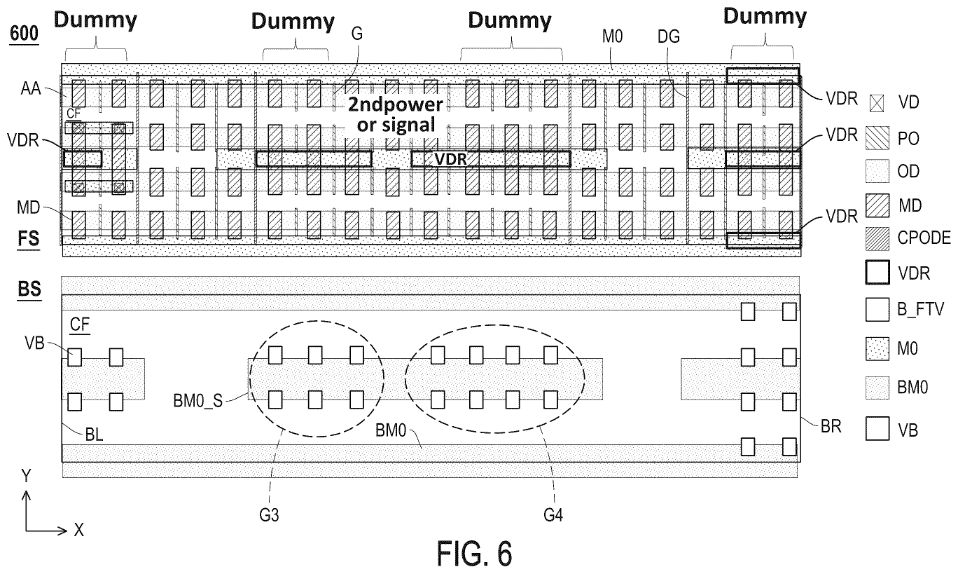

IC layout diagrams/devices 500 and 600 depicted in FIGS. 5 and 6 are similar to IC layout diagrams/devices 300 and 400 depicted in FIGS. 3 and 4, respectively, except that, instead of including a signal output pin that includes an instance of FTV region/structure B_FTV in backside BS that overlaps/overlies the instance of metal region/segment BM0_S and overlaps/underlies an instance of via region/structure VDR in frontside FS, each of the embodiments includes the signal output pin including a plurality of via regions/structures VB in backside BS that overlap/overlie the instance of metal region/segment BM0_S and two instances of via region/structure VDR in frontside FS that overlap/overlie the plurality of via regions/structures VB and overlap/underlie the instance of metal region/segment M0.

In IC layout diagrams/devices 500 and 600 depicted in FIGS. 5 and 6, the plurality of via regions/structures VB includes a group G3 of six instances of via region/structure VB corresponding to three instances of MD region/segment MD and a first instance of via region/structure VDR, and a group G4 of eight instances of via region/structure VB corresponding to four instances of MD region/segment MD and a second instance of via region/structure VDR. Other combinations of groups of instances of via region/structure VB, instances of MD region/segment MD, and/or instances of via region/structure VDR are within the scope of the present disclosure.

In various embodiments, the plurality of via regions/structures VB includes a single group G3 or G4 of instances of via region/structure VB or more than two groups G3 and/or G4 of instances of via region/structure VB, a given group G3 or G4 includes fewer than six or greater than eight instances of via region/structure VB, the number of instances of MD region/segment MD is fewer than six or greater than eight, and/or the number of instances of via region/structure VDR is one or greater than two.

Because the plurality of via regions/structures VB has a parallel arrangement, as a total number of instances of via region/structure VB increases, the signal output pin resistance decreases and an IR voltage drop due to current flow decreases. In some embodiments, the total number of instances of via region/structure VB in the plurality of via regions/structures VB corresponds to a specified signal load, e.g., current level, of a power supply, reference, clock, or other signal that functional cell CF is configured to propagate on the signal output pin.

By including the plurality of via regions/structures VB in the signal output pin, each of the embodiments depicted in FIGS. 5 and 6 is capable of propagating larger signal loads than in cases in which signal output pins include smaller numbers of instances of via region/structure VB.

In each of IC layout diagrams/devices 300-600 depicted in FIGS. 3-6, as the total number of instances of via region/structure VB increases, the value of a corresponding cell width, e.g., width W2, also increases, representing a tradeoff between cell area and the benefits discussed above.

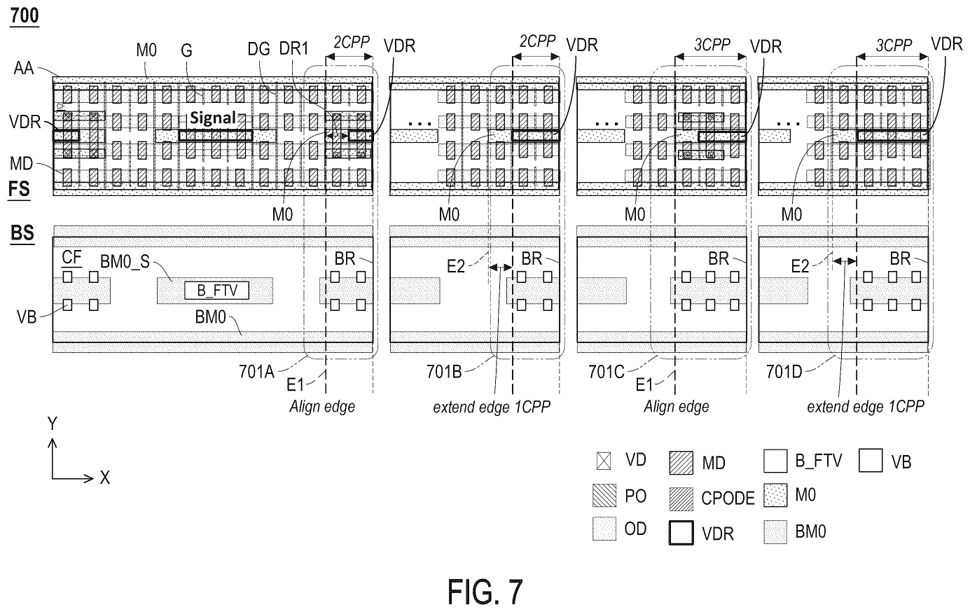

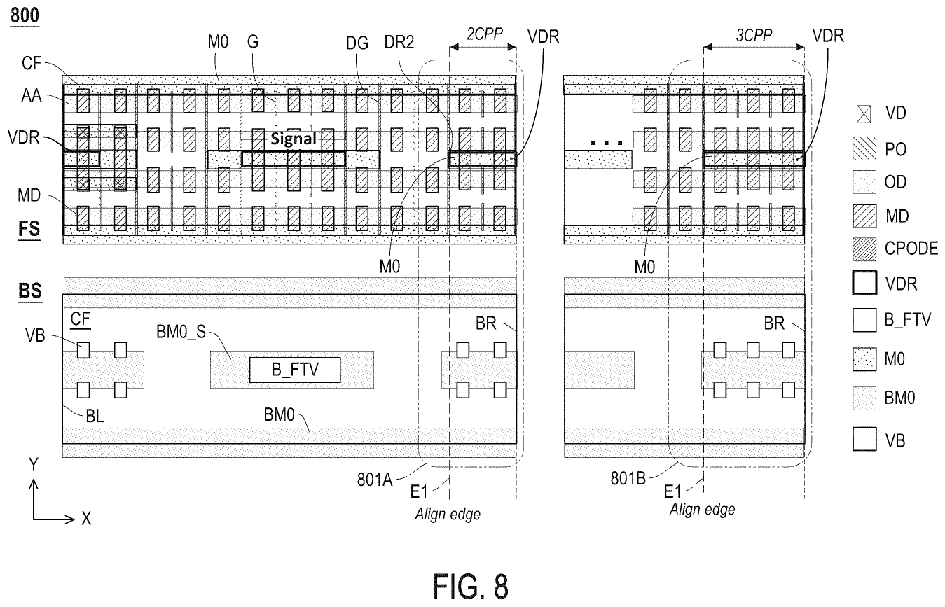

FIGS. 7 and 8 depict embodiments of respective IC layout diagrams/devices 700 and 800 in which the features of network component FS_net of a given instance of network 100 are configured. Each of FIGS. 7 and 8 depicts an instance of functional cell CF including alternative arrangements of a corresponding region 701A-701D, 801A, or 801B along border BR.

The embodiments depicted in FIG. 7 correspond to a design rule DR1 of the manufacturing process used to manufacture IC device 200 based on IC layout diagram 200 in which edges of instances of via region/structure VDR and overlapping/overlying instances of metal region/segment M0 have a minimum spacing of 1 CPP. The embodiments depicted in FIG. 7 correspond to the edges of instances of via region/structure VDR and overlapping/overlying instances of metal region/segment M0 being separated by a distance equal to the minimum spacing of 1 CPP of design rule DR1.

Region 701A includes the instance of via region/structure VDR extending 1 CPP and being separated from the align edge E1 by the design rule DR1, and network component FS_net including instances of via region/structure VD and additional instances of metal region/segment M0. Region 701B includes the instance of via region/structure VDR extending 2 CPP and being separated from the align edge E2 by the design rule DR1, and network component FS_net being free from including instances of via region/structure VD and additional instances of metal region/segment M0. Region 701C includes the instance of via region/structure VDR extending 2 CPP and network component FS_net including instances of via region/structure VD and being separated from the align edge E1 by the design rule DR1, and additional instances of metal region/segment M0. Region 701D includes the instance of via region/structure VDR extending 3 CPP and being separated from the align edge E2 by the design rule DR1, and network component FS_net being free from including instances of via region/structure VD and additional instances of metal region/segment M0.

The embodiments depicted in FIG. 8 correspond to design rule DR2 of the manufacturing process used to manufacture IC device 200 based on IC layout diagram 200 in which edges of instances of via region/structure VDR and overlapping/overlying instances of metal region/segment M0 have a minimum spacing of 0 CPP. The embodiments depicted in FIG. 8 correspond to the edges of instances of via region/structure VDR and overlapping/overlying instances of metal region/segment M0 being separated by a distance equal to the minimum spacing of 0 CPP of design rule DR0 such that the corresponding edges are aligned with each other at a corresponding same X location (labelled as align edge E1).

Region 801A includes the instance of via region/structure VDR extending 2 CPP and network component FS_net being free from including instances of via region/structure VD and additional instances of metal region/segment M0, and region 801B includes the instance of via region/structure VDR extending 3 CPP and network component FS_net being free from including instances of via region/structure VD and additional instances of metal region/segment M0.

FIG. 9 is a flowchart of method 900 of manufacturing an IC device, in accordance with some embodiments. Method 900 is operable to form some or all of one or more of IC devices 100-800 discussed above with respect to FIGS. 1A-8.

In some embodiments, performing some or all of the operations of method 900 is part of building a plurality of IC devices, e.g., transistors, logic gates, memory cells, interconnect structures, and/or other suitable devices, by performing a plurality of manufacturing operations, e.g., one or more of a lithography, diffusion, deposition, etching, planarizing, or other operation suitable for building the plurality of IC devices in a semiconductor wafer.

In some embodiments, the operations of method 900 are performed in the order depicted in FIG. 9. In some embodiments, the operations of method 900 are performed in an order other than the order depicted in FIG. 9. In some embodiments, one or more additional operations are performed before, during, and/or after the operations of method 900. In some embodiments, performing some or all of the operations of method 900 includes performing one or more operations as discussed below with respect to IC manufacturing system 1200 and FIG. 12.

At operation 902, a first component of a network is constructed in a frontside of a semiconductor substrate. Constructing the first component of the network includes forming first and second active areas, an MD segment over the first and second active areas, a via over the MD segment, and a metal segment over the via. In some embodiments, constructing the first component of the network includes constructing network component FS_net discussed above with respect to FIGS. 1A-8.

Constructing the first component of the network includes constructing a functional cell and a frontside via electrically connected to the functional cell. In some embodiments, constructing the functional cell and the frontside via electrically connected to the functional cell includes constructing an instance of cell C1 and an instance of via structure VDR electrically connected to cell C1 as discussed above with respect to FIGS. 1A-8.

In some embodiments, forming the first and second active areas, the MD segment over the first and second active areas, the via over the MD segment, and the metal segment over the via includes forming instances of active area AA, MD segment MD, via structure VDR, and metal segment M0 as discussed above with respect to FIGS. 1A-8.

In some embodiments, constructing the first component of the network includes forming additional MD segments over the first and second active areas, additional vias over the MD segments, and additional metal segments over the additional vias, e.g., forming additional instances of MD segment MD, instances of via structure VD and/or VDR, and additional instances of metal segment M0 as discussed above with respect to FIGS. 1A-8.

In some embodiments, constructing the first component of the network includes constructing one or more dummy transistors including forming one or more gates and one or more dummy gates, e.g., constructing dummy transistors including dummy transistors DM1 and/or DM2 and forming one or more instances of each of gate structure G and dummy gate structure DG as discussed above with respect to FIGS. 1A-8.

In some embodiments, constructing the first component of the network includes forming the network features corresponding to multiple cells, e.g., instances of one or both of boundary cell CB or functional cell CF discussed above with respect to FIGS. 1A-8.

In some embodiments, constructing the first component of the network includes performing a plurality of manufacturing processes including one or more of a lithography, diffusion, implantation, deposition, etching, planarizing, or other operation suitable for constructing the first component of the network including frontside features arranged as discussed above with respect to FIGS. 1A-8.

At operation 904, a second component of the network is constructed in a backside of the semiconductor substrate. Constructing the second component of the network includes forming a parallel arrangement of vias and a metal segment over the vias. In some embodiments, constructing the second component of the network includes constructing network component BS_net discussed above with respect to FIGS. 1A-8.

Constructing the second component of the network includes forming at least one backside via electrically connected to the functional cell constructed in operation 902. In some embodiments, forming the backside via electrically connected to the functional cell includes forming at least one instance of via structure VB electrically connected to cell C1 as discussed above with respect to FIGS. 1A-8.

In some embodiments, forming the parallel arrangement of vias and the metal segment over the vias includes forming instances of via structure VB and metal segment BM0 as discussed above with respect to FIGS. 1A-8.

In some embodiments, constructing the second component of the network includes forming the backside vias corresponding to multiple cells, e.g., instances of one or both of boundary cell CB or functional cell CF discussed above with respect to FIGS. 1A-8.

In some embodiments, forming the parallel arrangement of vias and the metal segment over the vias includes performing a plurality of manufacturing operations including depositing and patterning one or more photoresist layers, performing one or more etching processes, and performing one or more deposition processes whereby one or more conductive materials are configured to form a low resistance structure extending from the frontside feature to the backside of the semiconductor substrate.

At operation 906, in some embodiments, a power grid electrically connected to the network is constructed. In some embodiments, constructing the power grid includes constructing one of a power supply voltage distribution network or a reference voltage distribution network as discussed above with respect to FIGS. 1A-8.

In some embodiments, constructing the power grid electrically connected to the network includes forming one or more metal segments and vias electrically connected to one or both of frontside metal segment M0 or backside metal segment BM0 discussed above with respect to FIGS. 1A-8.

In some embodiments, constructing a power grid includes performing a plurality of manufacturing operations including depositing and patterning one or more photoresist layers, performing one or more etching processes, and performing one or more deposition processes whereby one or more conductive materials are configured to construct a continuous, low resistance structure.

By performing some or all of the operations of method 900, an IC device is manufactured in which an electrical connection between a cell and a network includes multiple parallel paths between frontside and backside network components, thereby enabling the realization of the benefits discussed above with respect to IC devices 100 and 200.

FIG. 10 is a flowchart of method 1000 of manufacturing an IC device, e.g., one or more of IC devices 100-800 based on IC layout diagrams 100-800 discussed above with respect to FIGS. 1A-8, in accordance with some embodiments.

In some embodiments, manufacturing the IC device includes generating the IC layout diagram corresponding to the IC device, e.g., IC device 100-800 discussed above with respect to FIGS. 1A-8.

In some embodiments, some or all of method 1000 is executed by a processor of a computer, e.g., a processor 1102 of an IC layout diagram generation system 1100, discussed below with respect to FIG. 11.

Some or all of the operations of method 1000 are capable of being performed as part of a design procedure performed in a design house, e.g., a design house 1220 discussed below with respect to FIG. 12.

In some embodiments, the operations of method 1000 are performed in the order depicted in FIG. 10. In some embodiments, the operations of method 1000 are performed simultaneously and/or in an order other than the order depicted in FIG. 10. In some embodiments, one or more operations are performed before, between, during, and/or after performing one or more operations of method 1000.

At operation 1002, in some embodiments, a frontside of a network is arranged in an IC layout diagram. Arranging the frontside of the network includes arranging first and second adjacent active regions in the IC layout diagram, overlapping each of the first active region and the second active region with first and second MD regions, overlapping the first MD region with a frontside via region between the first and second active regions, and overlapping the frontside via region with a frontside metal region extending between the first and second active regions. In some embodiments, arranging the frontside of the network includes arranging frontside network component FS_net of network 100 discussed above with respect to FIGS. 1A-8.

In some embodiments, arranging the frontside of the network includes arranging a functional cell including a frontside via region. In some embodiments, arranging the functional cell including the frontside via region includes arranging cell C1 including via region VDR discussed above with respect to FIGS. 1A-8.

In some embodiments, arranging the first and second adjacent active regions in the IC layout diagram, overlapping each of the first active region and the second active region with first and second MD regions, overlapping the first MD region with the frontside via region between the first and second active regions, and overlapping the frontside via region with a frontside metal region extending between the first and second active regions includes arranging instances of active region AA, MD segment MD, via region VDR, and metal region M0 discussed above with respect to FIGS. 1A-8.

In some embodiments, arranging the frontside of the network includes overlapping the first active region and the second active region with at least one additional MD region, overlapping the second and/or at least one additional MD region with at least one additional frontside via region, and overlapping the at least one additional frontside via region with at least one additional frontside metal region, e.g., arranging additional instances of MD region MD, via region VD and/or VDR, and/or metal region M0 as discussed above with respect to FIGS. 1A-8.

In some embodiments, arranging the frontside of the network includes arranging at least one dummy transistor by overlapping the first active region and the second active region with at least one gate region and one dummy gate region, e.g., arranging dummy transistors including dummy transistors DM1 and/or DM2 and arranging at least one instance of each of gate region G and dummy gate region DG as discussed above with respect to FIGS. 1A-8.

In some embodiments, arranging the frontside of the network includes arranging a portion of the frontside of the network corresponding to a single cell, e.g., boundary cell CB or functional cell CF, or arranging a portion or all of the frontside of the network corresponding to multiple cells, e.g., instances of cell C1, boundary cell CB, and/or functional cell CF, as discussed above with respect to FIGS. 1A-8.

At operation 1004, in some embodiments, a backside of the network including a parallel arrangement of via regions is arranged in the IC layout diagram. Arranging the backside of the network includes overlapping each of the first active region and the first MD region with a first backside via region, overlapping each of the first active region and the second MD region with a second backside via region, overlapping each of the second active region and the first MD region with a third backside via region, and overlapping each of the second active region and the second MD region with a fourth backside via region. In some embodiments, arranging the backside of the network includes arranging backside network component BS_net of network 100 discussed above with respect to FIGS. 1A-8.

In some embodiments, arranging the backside of the network includes further arranging the functional cell arranged in operation 1002 by including at least one backside via region in the functional cell. In some embodiments, including the at least one backside via region includes arranging cell C1 by including at least one instance of backside via region VB discussed above with respect to FIGS. 1A-8.

In some embodiments, arranging the parallel arrangement of via regions includes arranging instances of via region VB discussed above with respect to FIGS. 1A-8.

In some embodiments, arranging the parallel arrangement of via regions includes overlapping the backside via regions with at least one metal segment of the backside of the network, e.g., overlapping instances of via region VB with at least one instance of metal region BM0 as discussed above with respect to FIGS. 1A-8.

In some embodiments, arranging the backside of the network includes arranging a portion of the backside of the network corresponding to a single cell, e.g., boundary cell CB or functional cell CF, or arranging a portion or all of the backside of the network corresponding to multiple cells, e.g., instances of cell C1, boundary cell CB, and/or functional cell CF, as discussed above with respect to FIGS. 1A-8.

In some embodiments, arranging the backside of the network includes, prior to overlapping the first and second active regions and first and second MD regions with the first through fourth backside via regions, determining that a total number of electrical connections between a frontside network and a backside network is below a minimum number of electrical connections.

In some embodiments, determining that a total number of electrical connections between a frontside network and a backside network is below a minimum number of electrical connections includes the minimum number of electrical connections being equal to nine, e.g., based on one or more design criteria as discussed above with respect to FIGS. 1A-8.

In some embodiments, arranging the backside of the network includes, prior to overlapping the first and second active regions and first and second MD regions with the first through fourth backside via regions, determining that a total number of electrical connections of an output signal pin is below a minimum number of electrical connections based on one or more design criteria as discussed above with respect to FIGS. 5 and 6.

At operation 1006, in some embodiments, the cell including the via regions is stored in a cell library. In some embodiments, storing the cell includes storing one or more instances of cell C1, boundary cell CB, or functional cell CF discussed above with respect to FIGS. 1A-8.

In some embodiments, storing the cell in the cell library includes storing the cell in a non-volatile, computer-readable memory or a database and/or includes storing the cell over a network. In some embodiments, storing the cell in the cell library includes storing the cell in cell library 1107 and/or over network 1114 of IC layout diagram generation system 1100, discussed below with respect to FIG. 11.

At operation 1008, in some embodiments, the cell including the via regions is placed in the IC layout diagram. In some embodiments, placing the cell in the IC layout diagram includes placing one or more instances of cell C1, boundary cell CB, or functional cell CF in an IC layout diagram, e.g., IC layout diagram 100-800 discussed above with respect to FIGS. 1A-8.

At operation 1010, in some embodiments, power grid connections to the network are arranged. In some embodiments, arranging the power grid connections includes arranging one of a power supply voltage distribution network or a reference voltage distribution network as discussed above with respect to FIGS. 1A-8.

In some embodiments, arranging the power grid connections includes overlapping at least one instance of frontside metal region M0 or backside metal region BM0 with one or more instances of a corresponding frontside or backside via and/or metal region as discussed above with respect to FIGS. 1A-8.

At operation 1012, in some embodiments, the IC layout diagram including the cell (including the FTV region) is stored in a storage device. In some embodiments, storing the IC layout diagram in the storage device includes storing one or more of IC layout diagrams 100-800, discussed above with respect to FIGS. 1A-8, in the storage device.

In some embodiments, storing the IC layout diagram in the storage device includes storing the IC layout diagram, e.g., IC layout diagram 100-800, in a non-volatile, computer-readable memory or a database, and/or includes storing the IC layout diagram over a network. In some embodiments, storing the IC layout diagram in the storage device includes storing the IC layout diagram in layout diagrams 1109 and/or over network 1114 of IC layout diagram generation system 1100, discussed below with respect to FIG. 11.

At operation 1014, in some embodiments, one or more manufacturing operations, one or more lithographic exposures, are performed based on the IC layout diagram. Non-limiting examples of performing one or more manufacturing operations, e.g., one or more lithographic exposures, based on the IC layout diagram are discussed above with respect to FIG. 9 and below with respect to FIG. 12.

By executing some or all of the operations of method 1000, an IC layout diagram is generated corresponding to an IC device in which an electrical connection between a cell and a network includes multiple parallel paths between frontside and backside network components, thereby enabling the realization of the benefits discussed above with respect to IC devices 100-800.

FIG. 11 is a block diagram of IC layout diagram generation system 1100, in accordance with some embodiments. Methods described herein of designing IC layout diagrams in accordance with one or more embodiments are implementable, for example, using IC layout diagram generation system 1100, in accordance with some embodiments.

In some embodiments, IC layout diagram generation system 1100 is a general purpose computing device including a hardware processor 1102 and a non-transitory, computer-readable storage medium 1104. Storage medium 1104, amongst other things, is encoded with, i.e., stores, computer program code 1106, i.e., a set of executable instructions. Execution of instructions 1106 by hardware processor 1102 represents (at least in part) an electronic design automation (EDA) tool which implements a portion or all of a method, e.g., method 1000 of manufacturing an IC device described above with respect to FIG. 10 (hereinafter, the noted processes and/or methods).

Processor 1102 is electrically coupled to computer-readable storage medium 1104 via a bus 1108. Processor 1102 is also electrically coupled to an I/O interface 1110 by bus 1108. A network interface 1112 is also electrically connected to processor 1102 via bus 1108. Network interface 1112 is connected to a network 1114, so that processor 1102 and computer-readable storage medium 1104 are capable of connecting to external elements via network 1114. Processor 1102 is configured to execute computer program code 1106 encoded in computer-readable storage medium 1104 in order to cause IC layout diagram generation system 1100 to be usable for performing a portion or all of the noted processes and/or methods. In one or more embodiments, processor 1102 is a central processing unit (CPU), a multi-processor, a distributed processing system, an application specific integrated circuit (ASIC), and/or a suitable processing unit.

In one or more embodiments, computer-readable storage medium 1104 is an electronic, magnetic, optical, electromagnetic, infrared, and/or a semiconductor system (or apparatus or device). For example, computer-readable storage medium 1104 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 1104 includes a compact disk-read only memory (CD-ROM), a compact disk-read/write (CD-R/W), and/or a digital video disc (DVD).

In one or more embodiments, computer-readable storage medium 1104 stores computer program code 1106 configured to cause IC layout diagram generation system 1100 (where such execution represents (at least in part) the EDA tool) to be usable for performing a portion or all of the noted processes and/or methods. In one or more embodiments, computer-readable storage medium 1104 also stores information which facilitates performing a portion or all of the noted processes and/or methods.

In one or more embodiments, computer-readable storage medium 1104 stores cell library 1107 of cells including such cells as disclosed herein, e.g., cells corresponding to IC layout diagrams 100-800 discussed above with respect to FIGS. 1A-8.

In one or more embodiments, computer-readable storage medium 1104 stores layout diagrams 1109 including such IC layout diagrams as disclosed herein, e.g., IC layout diagrams 100-800 discussed above with respect to FIGS. 1A-8.

IC layout diagram generation system 1100 includes I/O interface 1110. I/O interface 1110 is coupled to external circuitry. In one or more embodiments, I/O interface 1110 includes a keyboard, keypad, mouse, trackball, trackpad, touchscreen, and/or cursor direction keys for communicating information and commands to processor 1102.

IC layout diagram generation system 1100 also includes network interface 1112 coupled to processor 1102. Network interface 1112 allows system 1100 to communicate with network 1114, to which one or more other computer systems are connected. Network interface 1112 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more IC layout diagram generation systems 1100.

IC layout diagram generation system 1100 is configured to receive information through I/O interface 1110. The information received through I/O interface 1110 includes one or more of instructions, data, design rules, libraries of standard cells, and/or other parameters for processing by processor 1102. The information is transferred to processor 1102 via bus 1108. IC layout diagram generation system 1100 is configured to receive information related to a UI through I/O interface 1110. The information is stored in computer-readable medium 1104 as user interface (UI) 1142.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by IC layout diagram generation system 1100. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 12 is a block diagram of IC manufacturing system 1200, and an IC manufacturing flow associated therewith, in accordance with some embodiments. In some embodiments, based on an IC layout diagram, at least one of (A) one or more semiconductor masks or (B) at least one component in a layer of a semiconductor integrated circuit is fabricated using manufacturing system 1200.

In FIG. 12, IC manufacturing system 1200 includes entities, such as a design house 1220, a mask house 1230, and an IC manufacturer/fabricator (“fab”) 1250, that interact with one another in the design, development, and manufacturing cycles and/or services related to manufacturing an IC device 1260. The entities in system 1200 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1220, mask house 1230, and IC fab 1250 is owned by a single larger company. In some embodiments, two or more of design house 1220, mask house 1230, and IC fab 1250 coexist in a common facility and use common resources.

Design house (or design team) 1220 generates an IC design layout diagram 1222. IC design layout diagram 1222 includes various geometrical patterns, e.g., one or more of IC layout diagrams 100-800 discussed above with respect to FIGS. 1A-8. The geometrical patterns correspond to patterns of metal, oxide, or semiconductor layers that make up the various components of IC device 1260 to be fabricated. The various layers combine to form various IC features. For example, a portion of IC design layout diagram 1222 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1220 implements a proper design procedure to form IC design layout diagram 1222. The design procedure includes one or more of logic design, physical design or place and route. IC design layout diagram 1222 is presented in one or more data files having information of the geometrical patterns. For example, IC design layout diagram 1222 can be expressed in a GDSII file format or DFII file format.

Mask house 1230 includes data preparation 1232 and mask fabrication 1244. Mask house 1230 uses IC design layout diagram 1222 to manufacture one or more masks 1245 to be used for fabricating the various layers of IC device 1260 according to IC design layout diagram 1222. Mask house 1230 performs mask data preparation 1232, where IC design layout diagram 1222 is translated into a representative data file (RDF). Mask data preparation 1232 provides the RDF to mask fabrication 1244. Mask fabrication 1244 includes a mask writer. A mask writer converts the RDF to an image on a substrate, such as a mask (reticle) 1245 or a semiconductor wafer 1253. The design layout diagram 1222 is manipulated by mask data preparation 1232 to comply with particular characteristics of the mask writer and/or requirements of IC fab 1250. In FIG. 12, mask data preparation 1232 and mask fabrication 1244 are illustrated as separate elements. In some embodiments, mask data preparation 1232 and mask fabrication 1244 can be collectively referred to as mask data preparation.

In some embodiments, mask data preparation 1232 includes optical proximity correction (OPC) which uses lithography enhancement techniques to compensate for image errors, such as those that can arise from diffraction, interference, other process effects and the like. OPC adjusts IC design layout diagram 1222. In some embodiments, mask data preparation 1232 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1232 includes a mask rule checker (MRC) that checks the IC design layout diagram 1222 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1222 to compensate for limitations during mask fabrication 1244, which may undo part of the modifications performed by OPC in order to meet mask creation rules.

In some embodiments, mask data preparation 1232 includes lithography process checking (LPC) that simulates processing that will be implemented by IC fab 1250 to fabricate IC device 1260. LPC simulates this processing based on IC design layout diagram 1222 to create a simulated manufactured device, such as IC device 1260. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1222.

It should be understood that the above description of mask data preparation 1232 has been simplified for the purposes of clarity. In some embodiments, data preparation 1232 includes additional features such as a logic operation (LOP) to modify the IC design layout diagram 1222 according to manufacturing rules. Additionally, the processes applied to IC design layout diagram 1222 during data preparation 1232 may be executed in a variety of different orders.

After mask data preparation 1232 and during mask fabrication 1244, a mask 1245 or a group of masks 1245 are fabricated based on the modified IC design layout diagram 1222. In some embodiments, mask fabrication 1244 includes performing one or more lithographic exposures based on IC design layout diagram 1222. In some embodiments, an electron-beam (e-beam) or a mechanism of multiple e-beams is used to form a pattern on a mask (photomask or reticle) 1245 based on the modified IC design layout diagram 1222. Mask 1245 can be formed in various technologies. In some embodiments, mask 1245 is formed using binary technology. In some embodiments, a mask pattern includes opaque regions and transparent regions. A radiation beam, such as an ultraviolet (UV) or EUV beam, used to expose the image sensitive material layer (e.g., photoresist) which has been coated on a wafer, is blocked by the opaque region and transmits through the transparent regions. In one example, a binary mask version of mask 1245 includes a transparent substrate (e.g., fused quartz) and an opaque material (e.g., chromium) coated in the opaque regions of the binary mask. In another example, mask 1245 is formed using a phase shift technology. In a phase shift mask (PSM) version of mask 1245, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1244 is used in a variety of processes. For example, such a mask(s) is used in an ion implantation process to form various doped regions in semiconductor wafer 1253, in an etching process to form various etching regions in semiconductor wafer 1253, and/or in other suitable processes.

IC fab 1250 is an IC fabrication business that includes one or more manufacturing facilities for the fabrication of a variety of different IC products. In some embodiments, IC Fab 1250 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1250 includes wafer fabrication tools 1252 configured to execute various manufacturing operations on semiconductor wafer 1253 such that IC device 1260 is fabricated in accordance with the mask(s), e.g., mask 1245. In various embodiments, fabrication tools 1252 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1250 uses mask(s) 1245 fabricated by mask house 1230 to fabricate IC device 1260. Thus, IC fab 1250 at least indirectly uses IC design layout diagram 1222 to fabricate IC device 1260. In some embodiments, semiconductor wafer 1253 is fabricated by IC fab 1250 using mask(s) 1245 to form IC device 1260. In some embodiments, the IC fabrication includes performing one or more lithographic exposures based at least indirectly on IC design layout diagram 1222. Semiconductor wafer 1253 includes a silicon substrate or other proper substrate having material layers formed thereon. Semiconductor wafer 1253 further includes one or more of various doped regions, dielectric features, multilevel interconnects, and the like (formed at subsequent manufacturing steps).

In some embodiments, an IC device includes first and second adjacent active areas extending in a first direction in a front side of a semiconductor substrate, first and second adjacent MD segments extending in a second direction perpendicular to the first direction, wherein each of the first MD segment and the second MD segment overlies and is electrically connected to each of the first active area and the second active area, a frontside via overlying and electrically connected to the first MD segment between the first active area and the second active area, a frontside metal segment overlying and electrically connected to the frontside via and extending in the first direction, a backside metal segment extending in the first direction, first and second backside vias extending between and electrically connected to each of the backside metal segment and the first active area, and third and fourth backside vias extending between and electrically connected to each of the backside metal segment and the second active area, wherein each of the first backside via and the third backside via is aligned with the first MD segment in a third direction perpendicular to the first and second directions, and each of the second backside via and the fourth backside via is aligned with the second MD segment in the third direction. In some embodiments, the frontside via overlies and is electrically connected to the second MD segment between the first active area and the second active area. In some embodiments, the IC device includes first and second dummy gates extending in the second direction and overlying each of the first active area and the second active area, wherein the first dummy gate and the second dummy gate are separated by a distance of two or three times a gate pitch of the IC device, and the frontside via is between the first dummy gate and the second dummy gate. In some embodiments, the frontside via is a first frontside via, the frontside metal segment is a first frontside metal segment, and the IC device includes second and third frontside vias overlying and electrically connected to the first MD segment, fourth and fifth frontside vias overlying and electrically connected to the second MD segment, a second frontside metal segment overlying and electrically connected to each of the second frontside via and the fourth frontside via, and a third frontside metal segment overlying and electrically connected to each of the third frontside via and the fifth frontside via. In some embodiments, the IC device includes first and second dummy gates extending in the second direction and overlying each of the first active area and the second active area, wherein the first dummy gate and the second dummy gate are separated by a distance of two or three times a gate pitch of the IC device, and each of the first through fifth frontside vias is between the first dummy gate and the second dummy gate. In some embodiments, the backside metal segment includes an edge adjacent to each of the of the second backside via and the fourth backside via in the first direction. In some embodiments, the backside metal segment is a first backside metal segment, and the IC device includes a second backside metal segment aligned with the first backside metal segment and adjacent to the edge of the first backside metal segment. In some embodiments, the first backside metal segment, the first through fourth backside vias, the first and second active areas, the first and second MD segments, the frontside via, and the frontside metal segment are configured as part of a first power distribution network, and the second backside metal segment is configured as part of a second power distribution network or a signal path.

In some embodiments, a method of manufacturing an IC device includes forming first and second adjacent active areas in a front side of a semiconductor substrate, forming first and second MD segments perpendicular to and on each of the first active area and the second active area, constructing a frontside via on the first MD segment between the first active area and the second active area, constructing a frontside metal segment on the frontside via and extending between the first and second active areas, constructing a first backside via on the first active area and aligned with the first MD segment, constructing a second backside via on the first active area and aligned with the second MD segment, constructing a third backside via on the second active area and aligned with the first MD segment, constructing a fourth backside via on the second active area and aligned with the second MD segment, and constructing a backside metal segment on each of the first through fourth backside vias and aligned with the frontside metal segment. In some embodiments, constructing the frontside via on the first MD segment includes constructing the frontside via on the second MD segment between the first active area and the second active area. In some embodiments, the frontside via is a first frontside via, the frontside metal segment is a first frontside metal segment, constructing the first frontside via includes constructing second and third frontside vias on the first MD segment and constructing fourth and fifth frontside vias on the second MD segment, and constructing the frontside metal segment includes constructing a second frontside metal segment on each of the second frontside via and the fourth frontside via and constructing a third frontside metal segment on each of the third frontside via and the fifth frontside via. In some embodiments, the method includes constructing first and second dummy gates overlying each of the first active area and the second active area and separated by a distance of two or three times a gate pitch of the IC device, wherein the forming the first and second MD segments includes forming the first and second MD segments between the first dummy gate and the second dummy gate. In some embodiments, constructing the backside metal segment includes forming an edge of the backside metal segment adjacent to each of the second backside via and the fourth backside via. In some embodiments, the backside metal segment is a first backside metal segment, and constructing the backside metal segment includes constructing a second backside metal segment aligned with the first backside metal segment and adjacent to the edge of the first backside metal segment.

In some embodiments, a method of manufacturing an IC device includes arranging first and second adjacent active regions in an IC layout diagram, overlapping each of the first active region and the second active region with first and second MD regions, overlapping the first MD region with a frontside via region between the first and second active regions, overlapping the frontside via region with a frontside metal region extending between the first and second active regions, overlapping a first backside via region with each of the first active region and the first MD region, overlapping a second backside via region with each of the first active region and the second MD region, overlapping a third backside via region with each of the second active region and the first MD region, overlapping a fourth backside via region with each of the second active region and the second MD region, overlapping a backside metal region with each of the first through fourth backside via regions and the frontside metal region, storing the IC layout diagram including the first and second active regions, the first and second MD regions, the frontside via region, the frontside metal region, the first through fourth backside via regions, and the backside metal region in a storage device, and using the stored IC layout diagram to perform a manufacturing operation. In some embodiments, the method includes determining a minimum number of electrical connections of a power distribution network based on one or more design rules. In some embodiments, the method includes prior to the overlapping the first through fourth backside via regions with each of the first and second active regions and first and second MD regions, determining that a total number of electrical connections between a frontside component of the power distribution network and a backside component of the power distribution network is below the minimum number of electrical connections, wherein the frontside network includes the frontside metal region, and the backside network includes the backside metal region. In some embodiments, the overlapping the backside metal region with each of the first through fourth backside via regions and the frontside metal region includes aligning the backside metal region with another backside metal region included in another power distribution network or a signal path. In some embodiments, the method includes overlapping each of the first active region and the second active region with first and second dummy gate regions separated by a distance of two or three times a gate pitch, wherein the first and second MD regions are between the first dummy gate region and the second dummy gate region. In some embodiments, one of overlapping the first MD region with the frontside via region includes overlapping the second MD region with the frontside via region between the first and second active regions, or the frontside via region is a first frontside via region, the frontside metal region is a first frontside metal region, overlapping the first MD region with the frontside via region includes overlapping the first MD region with second and third frontside via regions and overlapping the second MD region with fourth and fifth frontside via regions, and overlapping the frontside via region with the frontside metal region includes overlapping each of the second frontside via region and the fourth frontside via region with a second frontside metal region and overlapping each of the third frontside via region and the fifth frontside via region with a third frontside metal region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device comprising:
first and second adjacent active areas extending in a first direction in a front side of a semiconductor substrate;
first and second adjacent metal-diffusion (MD) segments extending in a second direction perpendicular to the first direction, wherein each of the first MD segment and the second MD segment overlies and is electrically connected to each of the first active area and the second active area;
a frontside via overlying and electrically connected to the first MD segment between the first active area and the second active area;
a frontside metal segment overlying and electrically connected to the frontside via and extending in the first direction;
a backside metal segment extending in the first direction;
first and second backside vias extending between and electrically connected to each of the backside metal segment and the first active area; and
third and fourth backside vias extending between and electrically connected to each of the backside metal segment and the second active area,
wherein
each of the first backside via and the third backside via is aligned with the first MD segment in a third direction perpendicular to the first and second directions, and
each of the second backside via and the fourth backside via is aligned with the second MD segment in the third direction.

2. The IC device of claim 1, wherein
the frontside via overlies and is electrically connected to the second MD segment between the first active area and the second active area.

3. The IC device of claim 2, further comprising:
first and second dummy gates extending in the second direction and overlying each of the first active area and the second active area,
wherein
the first dummy gate and the second dummy gate are separated by a distance of two or three times a gate pitch of the IC device, and
the frontside via is between the first dummy gate and the second dummy gate.

4. The IC device of claim 1, wherein
the frontside via is a first frontside via,
the frontside metal segment is a first frontside metal segment, and
the IC device further comprises:
second and third frontside vias overlying and electrically connected to the first MD segment;
fourth and fifth frontside vias overlying and electrically connected to the second MD segment;
a second frontside metal segment overlying and electrically connected to each of the second frontside via and the fourth frontside via; and
a third frontside metal segment overlying and electrically connected to each of the third frontside via and the fifth frontside via.

5. The IC device of claim 4, further comprising:
first and second dummy gates extending in the second direction and overlying each of the first active area and the second active area,
wherein
the first dummy gate and the second dummy gate are separated by a distance of two or three times a gate pitch of the IC device, and
each of the first through fifth frontside vias is between the first dummy gate and the second dummy gate.

6. The IC device of claim 1, wherein
the backside metal segment comprises an edge adjacent to each of the of the second backside via and the fourth backside via in the first direction.

7. The IC device of claim 6, wherein
the backside metal segment is a first backside metal segment, and
the IC device further comprises a second backside metal segment aligned with the first backside metal segment and adjacent to the edge of the first backside metal segment.

8. The IC device of claim 7, wherein
the first backside metal segment, the first through fourth backside vias, the first and second active areas, the first and second MD segments, the frontside via, and the frontside metal segment are configured as part of a first power distribution network, and
the second backside metal segment is configured as part of a second power distribution network or a signal path.

9. A method of manufacturing an integrated circuit (IC) device, the method comprising:
forming first and second adjacent active areas in a front side of a semiconductor substrate;
forming first and second metal-diffusion (MD) segments perpendicular to and on each of the first active area and the second active area;
constructing a frontside via on the first MD segment between the first active area and the second active area;
constructing a frontside metal segment on the frontside via and extending between the first and second active areas;
constructing a first backside via on the first active area and aligned with the first MD segment;
constructing a second backside via on the first active area and aligned with the second MD segment;
constructing a third backside via on the second active area and aligned with the first MD segment;
constructing a fourth backside via on the second active area and aligned with the second MD segment; and
constructing a backside metal segment on each of the first through fourth backside vias and aligned with the frontside metal segment.

10. The method of claim 9, wherein
the constructing the frontside via on the first MD segment comprises constructing the frontside via on the second MD segment between the first active area and the second active area.

11. The method of claim 9, wherein
the frontside via is a first frontside via,
the frontside metal segment is a first frontside metal segment,
the constructing the first frontside via comprises:
constructing second and third frontside vias on the first MD segment; and
constructing fourth and fifth frontside vias on the second MD segment, and the constructing the frontside metal segment comprises:
constructing a second frontside metal segment on each of the second frontside via and the fourth frontside via; and
constructing a third frontside metal segment on each of the third frontside via and the fifth frontside via.

12. The method of claim 9, further comprising:
constructing first and second dummy gates overlying each of the first active area and the second active area and separated by a distance of two or three times a gate pitch of the IC device,
wherein the forming the first and second MD segments comprises forming the first and second MD segments between the first dummy gate and the second dummy gate.

13. The method of claim 9, wherein
the constructing the backside metal segment comprises forming an edge of the backside metal segment adjacent to each of the second backside via and the fourth backside via.

14. The method of claim 13, wherein
the backside metal segment is a first backside metal segment, and
the constructing the backside metal segment further comprises constructing a second backside metal segment aligned with the first backside metal segment and adjacent to the edge of the first backside metal segment.

15. A method of manufacturing an integrated circuit (IC) device, the method comprising:
arranging first and second adjacent active regions in an IC layout diagram;
overlapping each of the first active region and the second active region with first and second metal-diffusion (MD) regions;
overlapping the first MD region with a frontside via region between the first and second active regions;
overlapping the frontside via region with a frontside metal region extending between the first and second active regions;
overlapping a first backside via region with each of the first active region and the first MD region;
overlapping a second backside via region with each of the first active region and the second MD region;
overlapping a third backside via region with each of the second active region and the first MD region;
overlapping a fourth backside via region with each of the second active region and the second MD region;
overlapping a backside metal region with each of the first through fourth backside via regions and the frontside metal region;
storing the IC layout diagram comprising the first and second active regions, the first and second MD regions, the frontside via region, the frontside metal region, the first through fourth backside via regions, and the backside metal region in a storage device; and
manufacturing the IC device based on the stored IC layout diagram.

16. The method of claim 15, further comprising:
determining a minimum number of electrical connections of a power distribution network based on one or more design rules.

17. The method of claim 16, further comprising:
prior to the overlapping the first through fourth backside via regions with each of the first and second active regions and first and second MD regions, determining that a total number of electrical connections between a frontside component of the power distribution network and a backside component of the power distribution network is below the minimum number of electrical connections,
wherein
the frontside network comprises the frontside metal region, and
the backside network comprises the backside metal region.

18. The method of claim 17, wherein
the overlapping the backside metal region with each of the first through fourth backside via regions and the frontside metal region comprises aligning the backside metal region with another backside metal region included in another power distribution network or a signal path.

19. The method of claim 15, further comprising:
overlapping each of the first active region and the second active region with first and second dummy gate regions separated by a distance of two or three times a gate pitch,
wherein the first and second MD regions are between the first dummy gate region and the second dummy gate region.

20. The method of claim 19, wherein one of:
the overlapping the first MD region with the frontside via region comprises overlapping the second MD region with the frontside via region between the first and second active regions; or
the frontside via region is a first frontside via region,
the frontside metal region is a first frontside metal region,
the overlapping the first MD region with the frontside via region comprises:
overlapping the first MD region with second and third frontside via regions; and
overlapping the second MD region with fourth and fifth frontside via regions, and
the overlapping the frontside via region with the frontside metal region comprises:
overlapping each of the second frontside via region and the fourth frontside via region with a second frontside metal region; and
overlapping each of the third frontside via region and the fifth frontside via region with a third frontside metal region.
